(19) United States
(12) Patent Application Publication
(10) Pub. No.: US 2010/0193351 A1
(43) Pub. Date: Aug. 5, 2010

(54) METHOD FOR PREPARING TRANSPARENT CONDUCTING FILM COATED WITH AZO/AG/AZO MULTILAYER THIN FILM

(75) Inventors: Soon-Gil YOON, Daejeon (KR); Hyun-Jin Cho, Daejeon (KR); Kyoung-Woo Park, Daejeon (KR)

Correspondence Address: STAAS & HALSEY LLP, SUITE 700, 1201 NEW YORK AVENUE, N.W., WASHINGTON, DC, 20005, US

(73) Assignee: THE INDUSTRY & ACADEMIC COOPERATION IN CHUNGNAM NATIONAL UNIVERSITY (IAC) of Republic of Korea

(21) Appl. No.: 12/392,462

(22) Filed: Feb. 25, 2009

(30) Foreign Application Priority Data
Feb. 5, 2009 (KR) 10-2009-0009167

(51) Int. Cl. C23C 14/34

(52) U.S. Cl. 204/192.15

(57) ABSTRACT

A method for preparing a transparent conducting film coated with an AZO/Ag/AZO multilayer thin film with low resistivity and high light transmittance, and a transparent conducting film produced by the same method. The method for preparing a transparent conducting film coated with an AZO/Ag/AZO multilayer thin film, includes (a) forming a primary AZO thin film on a substrate using an AZO target doped with Al through a sputtering method; (b) depositing Ag on the primary AZO thin film using the sputtering method to form a deposited Ag layer; and (c) forming a secondary AZO thin film on the Ag thin film using the AZO target doped with Al through a sputtering method.

### CROSS-REFERENCE TO RELATED APPLICATIONS

This application claims the benefit of Korean Application No. 10-2009-0009167, filed Feb. 5, 2009, in the Korean Intellectual Property Office, the disclosure of which is incorporated herein by reference.

### BACKGROUND

1. Field

The present invention relates to a method for preparing a transparent conducting film coated with an AZO/Ag/AZO multilayer thin film with low resistivity and high light transmittance, and a transparent conducting film produced by the same method.

2. Description of the Related Art

Recently, along with the development of the optics and electronics fields, the industrial demand for a transparent conducting film with high light transmittance and electrical conductivity is increasing. Such a transparent conducting film is necessarily used for a flat panel display device, a solar cell, a transparent touch panel and the like.

The transparent conducting film should satisfy the following several conditions:

First, low resistivity (10⁻⁵ Ω-cm or less),

Second, high light transmittance (85% or more in a visible light wavelength of 550 nm),

Third, stable damp heat properties in the IEC 1646 standard (treatment for 10,000 hours under the condition of a temperature of 85° C. and a humidity of 85%: Wennerberg, et al. Solar Energy Materials and Solar Cells, 75, 47 (2003)), and

Fourth, stable flexibility in a bending test of the transparent conducting film.

As a transparent conducting film which satisfies the above conditions at present, SnO₂:F, In₂O₃:Sn(ITO), Al-doped ZnO(AZO) thin films and the like are being spotlighted. Particularly, conventionally, ITO is widely used since it has a low resistivity (10⁻⁴ Ω-cm or less) and a high light transmittance of 85% in a visible light region. But, ITO has a limitation in its industrial use because of the price rise of ITO due to shortage of indium (In) as a raw material. Thus, the research is in progress on a new transparent conducting film which is low-priced and excellent in resistivity and light transmittance. In the meantime, since flexible organic light emitting diodes (OLEDs) attracting high interest currently should have a sheet resistance of 10¹ Ω/square or less, and a plasma display panel (PDP) optical filter should have a sheet resistance of 10⁰ Ω/square or less, materials having properties suitable for the OLEDs and PDP optical filter are required.

According to this requirement, Liu et al. (Thin Solid Films, 441, 200 (2003)) published that a ZnS/Ag/ZnS multilayer thin film is formed on a quartz substrate using a deposition method by thermal evaporation. In the meantime, Sahu et al. (Solar Energy Materials and Solar Cells, 91, 851 (2007)) suggested that a AZO/Ag/AZO multilayer thin film is formed on a glass substrate using electron beam evaporation.

However, these multilayer thin films entail a problem in that that the light transmittance thereof is apt to decrease drastically as the visible light wavelength band increases, as well as Figure of Merit (Ω⁻¹) indicating excellence of the transparent conducting film is less than 3.0×10⁻² Ω⁻¹, which is insufficient to be put into practical use of the transparent conducting film. In order to solve this problem, Sahu et al. suggested that these multiplayer thin films are thermally treated according to the temperature. However, such a thermal treatment method has a limitation that it can be applied to a glass or quartz substrate, but cannot be applied to a flexible substrate having no heat resistance like plastic. Furthermore, the thermal treatment method encounters a drawback in that it cannot also be applied to the flexible substrate having no heat resistance since a preparing process of such multilayer thin films is complicated and requires a high-temperature environment.

### SUMMARY

Additional aspects and/or advantages will be set forth in part in the description which follows and, in part, will be apparent from the description, or may be learned by practice of the invention.

Therefore, the present invention has been made in view of the above problems, and it is an object of the present invention to provide a method for preparing a transparent conducting film coated with an AZO/Ag/AZO multilayer thin film which satisfies the conditions of the transparent conducting film including low resistivity, high light transmittance, etc., without any thermal treatment, and a transparent conducting film produced by the method.

Another object of the present invention is to provide a method for preparing a transparent conducting film which is made of a flexible polymer material and is coated with an AZO/Ag/AZO multilayer thin film, and a transparent conducting film of a flexible polymer material produced by the same method.

In order to accomplish the above objects, the present invention provides a method for preparing a transparent conducting film coated with an AZO/Ag/AZO multilayer thin film, and a transparent conducting film produced by the same method.

(1) Preparation Method of Transparent Conducting Film

The present invention is directed to a method for preparing a transparent conducting film coated with an AZO/Ag/AZO multilayer thin film, the method comprising the steps of: (a) forming a primary AZO thin film on a substrate using an AZO target doped with Al through a sputtering method; (b) depositing Ag on the primary AZO thin film using the sputtering method to form a deposited Ag layer; and (c) forming a secondary AZO thin film on the Ag thin film using the AZO target doped with Al through the sputtering method.

In this case, the thickness of the deposited Ag layer ranges from 5 to 15 nm, more preferably ranges from 7 to 11 nm. When the thickness of the Ag layer is less than 5 nm, the Ag layer is apt to be not evenly deposited on the substrate. On the contrary, when the thickness of the Ag layer is more than 15 nm, the Ag layer exhibits a drastic decrease in light transmittance.

In the present invention, the thicknesses of the primary AZO thin film and the secondary AZO thin film are sufficient as long as it is suited for a typical light transmittance, but preferably range from 10 to 100 nm, respectively. When the thickness of the AZO thin film is very thin, its electrical conductivity decreases whereas when the thickness of the AZO thin film is very thick, its light transmittance decreases, which causes a problem.

In the present invention, the substrate may be a non-flexible substrate such as a glass substrate, a quartz substrate and the like, may be a flexible polymer substrate made of polyethersulfone, polyethylene terephthalate, Polycarbonate, polyimide or polyethylene naphthalate.

(2) Transparent Conducting Film

The present invention is directed to a transparent conducting film coated with an AZO/Ag/AZO multilayer thin film prepared by the preparing method of the transparent conducting film.

The transparent conducting film according to the present invention exhibits a low resistivity of 10⁻⁵ Ω-cm or less and a high light transmittance of 85% or more at a wavelength band of a visible light region ranging from 300 to 800 nm. Particularly, in case of the figure of merit used as an index of indicting excellence of the performance, when the Ag layer has a deposition thickness of 9 nm, it exhibits the highest figure of merit of 4.0×10⁻²Ω⁻¹. This figure of merit value is superior to the figure of merit values of 2.0×10⁻²Ω⁻¹ and 2.87×10⁻²Ω⁻¹ obtained by Lie et al. and Sahu et al. In addition, the sheet resistance and the light transmittance of the multilayer thin film are maintained stable without any change even after the damp heat treatment performed on the multilayer thin film for 1,000 hours under the condition where temperature is 85° C, and humidity is 85% as the IEC 1646 standard. Further, the result of the bending test of the transparent conducting film shows that there is no change in the adhesive force between the PES substrate and the multilayer thin film and the sheet resistances are the same within an error range.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a graph illustrating an X-ray diffraction pattern of a AZO/Ag/AZO multilayer thin film inserted with a variety of Ag layers having different thicknesses;

FIG. 2 is a graph illustrating an ω-scan of a multilayer thin film inserted with a variety of Ag layers having different thicknesses;

FIG. 3 is an SEM surface photograph and a TEM cross-section photograph of a multilayer thin film inserted with a variety of Ag layers having different thicknesses;

FIG. 4 is a graph illustrating a transmittance spectrum according to a visible light wavelength of a multilayer thin film inserted with a variety of Ag layers having different thicknesses;

FIG. 5 is a graph illustrating a transmittance at a wavelength of 550 nm of a multilayer thin film inserted with a variety of Ag layers having different thicknesses;

FIG. 6 is a graph illustrating the relationship between carrier concentration, carrier mobility and resistivity of a multilayer thin film inserted with a variety of Ag layers having different thicknesses;

FIG. 7 is a graph illustrating a Figure of merit of a multilayer thin film inserted with a variety of Ag layers having different thicknesses;

FIG. 8 is a graph illustrating a change in a sheet resistance according to damp heat treatment of a multilayer thin film according to one embodiment of the present invention;

FIG. 9 is a TEM cross-section photograph after damp heat treatment of a multilayer thin film according to one embodiment of the present invention;

FIG. 10 is a graph illustrating a change in light transmittance according to damp heat treatment of a multilayer thin film according to one embodiment of the present invention;

FIG. 11 is a graph illustrating a change in sheet resistance according to a bending distance of a multilayer thin film according to one embodiment of the present invention; and

FIG. 12 is a light microscope photograph illustrating a surface image according to a bending distance of a multilayer thin film according to one embodiment of the present invention.

### DETAILED DESCRIPTION OF EMBODIMENTS

Embodiments of the invention will be hereinafter described in detail with reference to the accompanying drawings. However, these embodiments of the present invention are merely illustrative of easy explanation on contents of the technical spirit and scope of the present invention, but the technical scope of the present invention is not limited or modified thereby. Also, it will be understood by those skilled in the art that various modifications and variations can be made to the present invention without departing from the spirit and scope of the appended claims.

In the following embodiments, the thicknesses of primary and secondary AZO thin films were set to 45nm known as the condition most susceptible for the damp heat treatment so as to be suited for the worst condition. It will be of course understood by a person skilled in the art that since even an AZO/Ag/AZO multilayer thin film prepared under such a susceptible condition exhibits a good effect, the primary and secondary AZO thin film having a variety of different thicknesses prepared under a better condition than the susceptible condition also exhibits a better effect. Accordingly, in the present invention, the thicknesses of the primary and secondary AZO thin film are not limited to the thicknesses as described in the embodiment below.

### Embodiments

### Embodiment 1

### Preparation of AZO/Ag/AZO Multilayer Thin Film

(1) Formation of Primary AZO Thin Film

First, a Si substrate or a flexible polyethersulfone (PES) substrate (thickness: 200 μm) having excellent thermal properties was washed, and then foreign substances on the substrate surface were removed using N2 gas. Then, the substrate was deposited at room temperature using an RF sputtering method so that the thickness of the AZO thin film is about 45 nm. During the deposition, an AZO target (with a diameter of 2 inches) doped with 2 wt % Al was sintered at 1400° C. using a ceramic process. An RF power applied to the AZO target was 30 W, a working vacuum pressure was maintained at 1.5 mTorr, a distance between the target and the substrate was about 10 cm, and Ar flow rate of 40 sccm (standard cc/min) was used as a sputtering gas.

(2) Deposition of Ag

An Ag thin film was deposited to a thickness of 3 nm to 20 nm in-situ on the primary AZO thin film formed by the above method using the Ag target at different deposition times under the condition where DC power is 30 W, deposition pressure is 3 mTorr and Ar flow rate is 10 sccm

The thickness of the Ag thin film of the AZO/Ag thin film deposited on the Si substrate was identified using a transmission electron microscope (TEM). For the purpose of controlling of the thickness of the Ag thin film, the thin film was deposited thickly in a pre-test and its thickness was measured through a cross-section of the deposited film by the SEM. Thereafter, the deposition time was determined such that the relationship between time and film thickness are shown and the thickness of a thin film is formed on an extension line thereof. It is impossible to observe the AZO/Ag thin film deposited on the PES substrate using the SEM or TEM, but it can be presumed that since the Ag layer is deposited on the AZO thin film deposited on the substrate, it is not nearly influenced by a material of which the substrate is made and has the same thickness as that of the Ag layer deposited on the Si substrate.

In the embodiments below, an experiment in which a surface or cross-section was observed using the SEM or TEM was carried out using a multilayer thin film deposited on the Si substrate, and other experiments except this were conducted on a multilayer thin film deposited on the PES substrate unless specifically stated otherwise.

(3) Formation of Secondary AZO Thin Film

Subsequently, a secondary AZO thin film was deposited in-situ on the Ag thin film using the same method under the same condition as that of (1) formation of the primary AZO thin film to thereby form an AZO(45 nm)/Ag/AZO(45 nm)/PES multilayer thin film.

### Embodiment 2

### Identification of Structure and Crystallinity of AZO/Ag/AZO Multilayer Thin Film

(1) Crystallinity

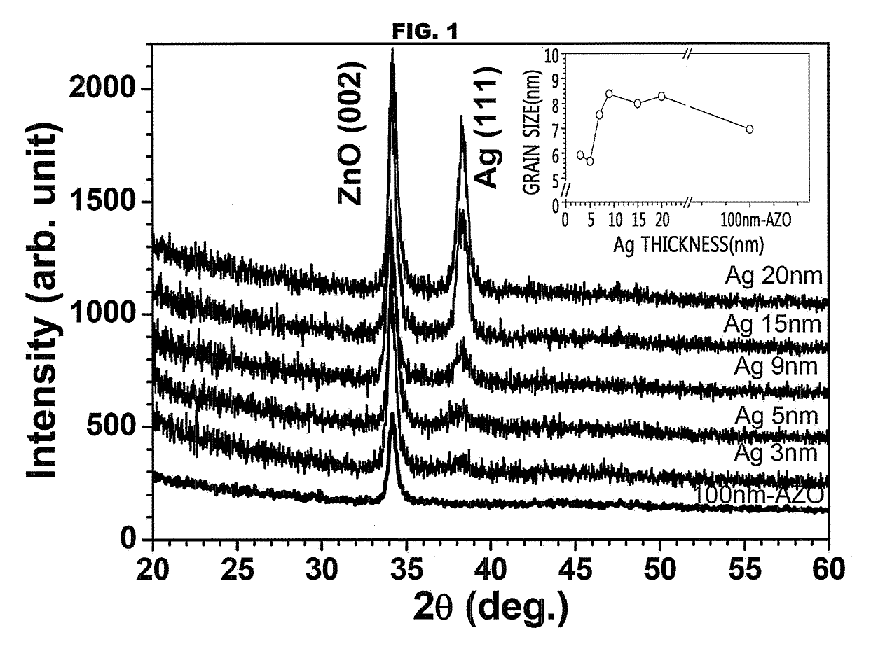

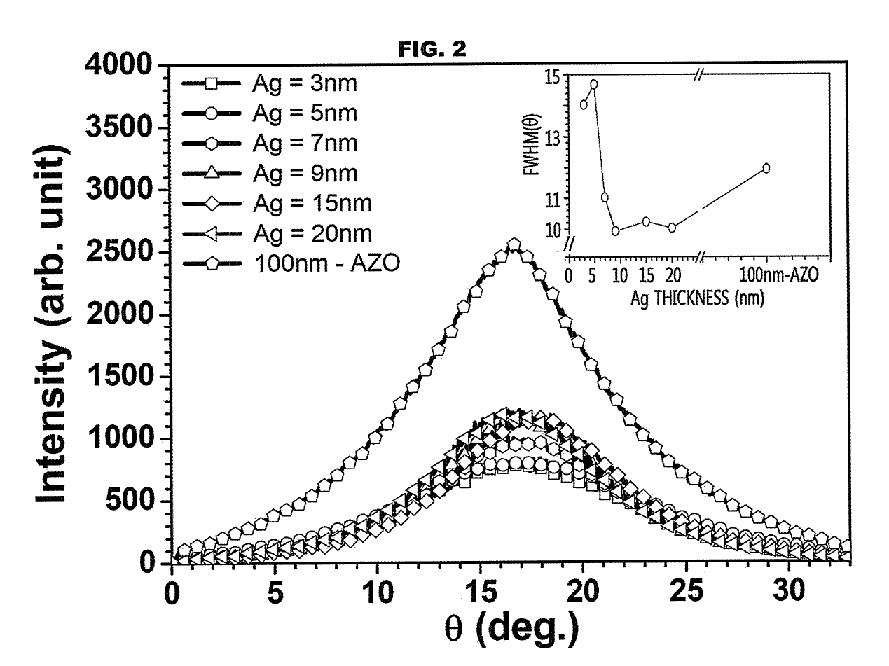

The crystal structure of the AZO and Ag layers was measured from the X-ray diffraction ((XRD, REGAKU D/MAX-RC) using a Cuka radiation and a nickel filer on the AZO/Ag/AZO multilayer thin film where the thickness of the Ag thin film prepared in the Embodiment 1 is 3, 5, 9, 15 and 20 nm, respectively, and the X-ray diffraction pattern was shown in FIG. 1. In addition, an w-scan was performed to identify crystallinity of the thin film, and its result was shown in FIG. 2.

It can be seen from FIG. 1 that the ZnO thin films deposited at room temperature were crystallized while exhibiting a (002) preferred orientation and the Ag layer was also grown while exhibiting a (111) preferred orientation. A small graph inside the graph of FIG. 1 shows the relationship between the Ag thickness and the grain size of the ZAO crystal calculated with a full-width-half-maximum (FWHM) of a ZnO (002) surface obtained from the XRD data. It can be seen from the inside graph that when the Ag thickness is more than 7 nm, the grain size of the AZO crystal is constant about 8 nm or so. The graph inside FIG. 2 shows the relationship between the Ag thickness and the full-width-half-maximum (FWHM) of a peak in the w-scan data. It can be seen from the inside graph that when the Ag thickness is more than 9 nm, it exhibits an excellent crystallinity having the smallest FWHM.

(2) Structure

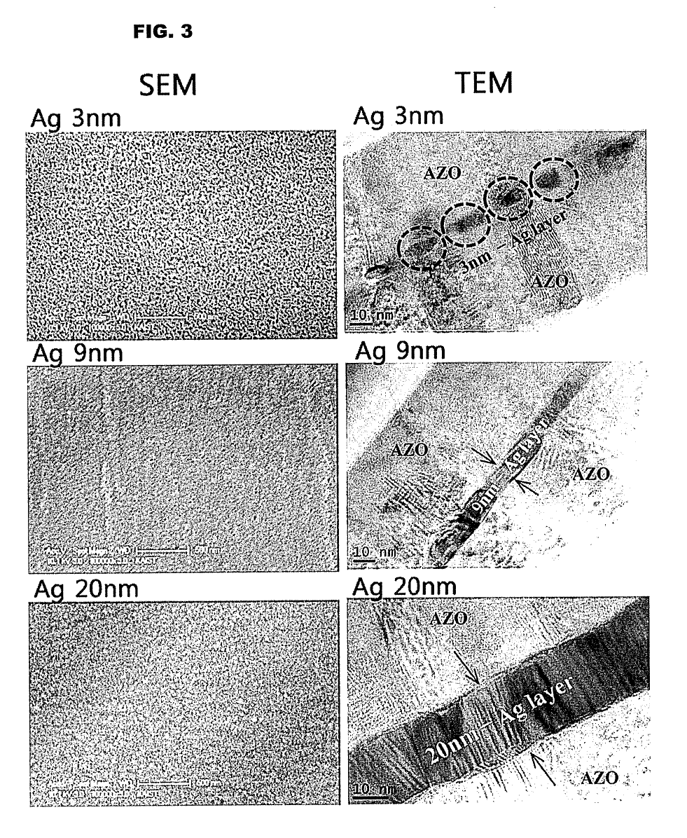

The microstructure of the Ag thin film which is deposited on the AZO thin film to a thickness of 5 nm, 9 nm and 20 nm, respectively, was observed by the SEM. Thereafter, photographs of the deposited Ag thin films were shown at the left side of FIG. 3. In the meantime, the cross-section of the AZO/Ag/AZO multilayer thin film where the thickness of the Ag thin film is 5 nm, 9 nm and 20 nm, respectively, was observed by the TEM to identify the thickness and structure of the Ag thin film interposed between the AZO layers, and then the photographs of its result were shown at the right side of FIG. 3, respectively.

It can be found from the photographs of FIG. 3 that when the Ag layer has a thickness of 3 nm, it looks as if it had holes in a state where it is not completely coated. On the contrary, when the Ag layer has a thickness of 9 nm or so, it shows a consecutively deposited state. In addition, it can be seen that when the Ag layer has a thickness of 20 nm, it also shows a consecutively deposited state.

### Embodiment 3

### Analysis of Electrical and Optical Properties of AZO/Ag/AZO Multilayer Thin Film

(1) Light Transmittance

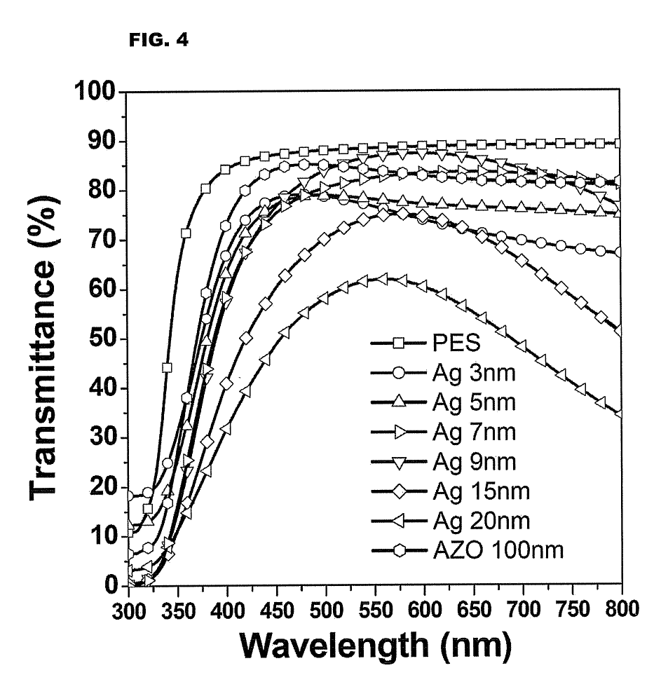

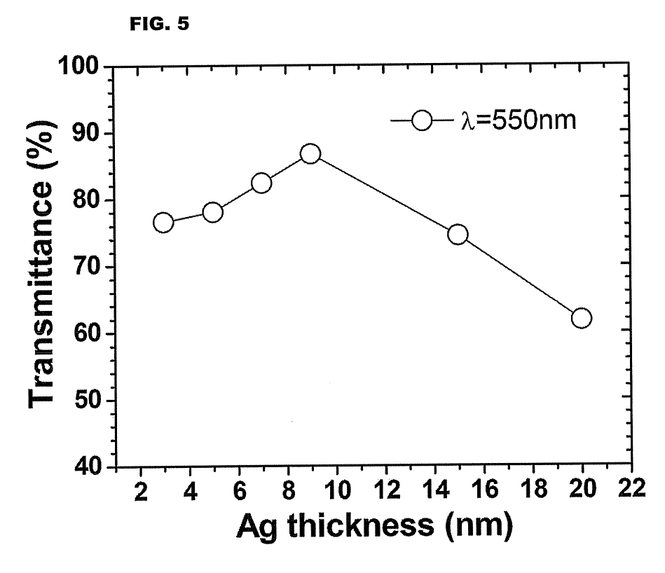

The light transmittance of the multilayer thin film prepared in Embodiment 1 was measured in the visible light region whose wavelength band ranges from 300 to 800 nm using a spectrophotometer (Shimadzu UV2450, Japan), and a spectrum of the light transmittance and a transmittance at a wavelength of 550 nm according to the thickness of Ag layers were shown in FIGS. 4 and 5, respectively.

As shown in FIGS. 4 and 5, as the thickness of the Ag layer increases from 3 nm to 9 nm, the light transmittance also increases. In the meantime, when the thickness of the Ag layer is more than 9 nm, the light transmittance decreases. It can be seen from this result that the thickness of the Ag layer has a great influence on the light transmittance.

(2) Resistivity

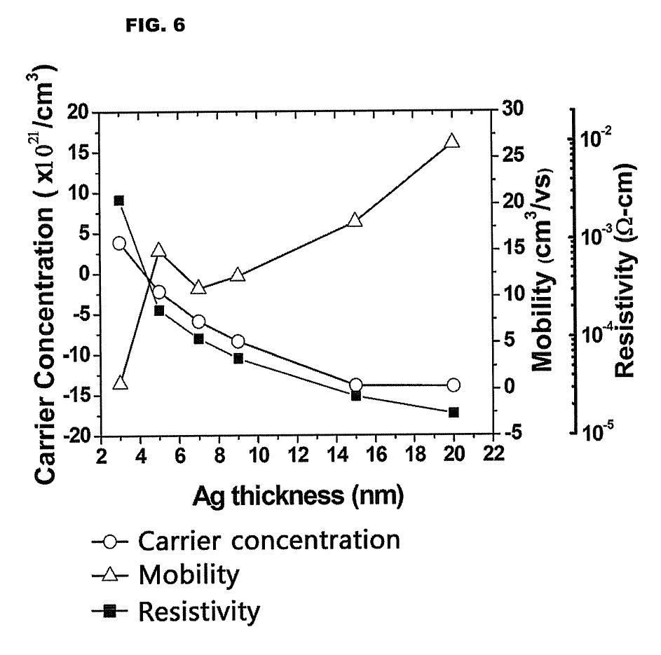

Carrier concentration and mobility of the multilayer thin film prepared in Embodiment 1 was measured using the Van de Pauw method, and resistivity of the multilayer thin film was obtained by the following Equation. Thereafter, the measurement results thereof were shown in FIG. 6.

Resistivity ρ=(neμ)−1

where n: carrier concentration, μ: carrier mobility, e: electron charge

It could be found from the graph of FIG. 6 that resistivity decreases with an increase in thickness of the Ag layer.

(3) Figure of Merit

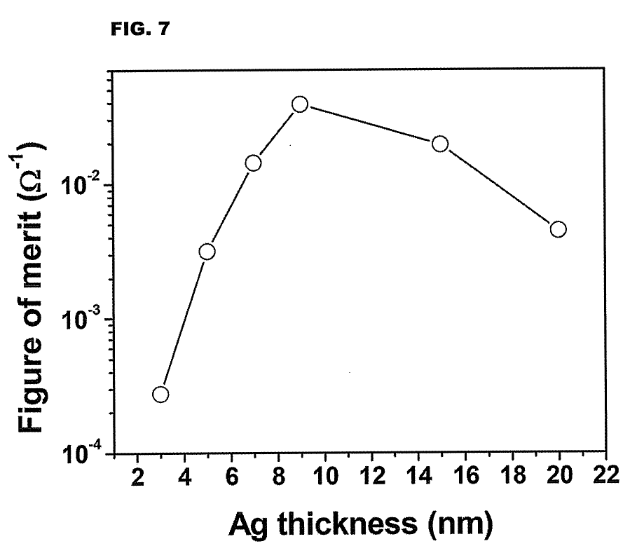

The transparent conducting film exhibits excellent properties as resistivity becomes lower and light transmittance becomes higher. However, since resistivity and light transmittance is not in a proportional relationship, figure of merit (Ω-1) is used as an index indicting excellence of the performance (Haacke, J. Appl. Phys. 47, 4086 (1976)). The figure of merit was calculated by the following Equation using the light transmittance measured in the above Embodiment 3 and sheet resistance, and the calculation result thereof was shown in FIG. 7.

Figure of merit FTC=T10/Rs

where T is light transmittance measured at a wavelength band of 550 nm, and Rs is a sheet resistance of the multilayer thin film, which was measured within a precision of ±0.5 Ω/sq using the four-point probe method (model CMT-SR 1000).

It can be found from the graph of FIG. 7 that when the Ag layer has a thickness of 9 nm, it exhibits the highest figure of merit of 4.0×10⁻²Ω⁻¹. This figure of merit value was superior to the figure of merit values of 2.0×10⁻²Ω⁻¹ and 2.87×10⁻² Ω−1

### Embodiment 4

### Damp Heat Test of AZO/Ag/AZO Multilayer Thin Film

In order to identify a damp heat resistance of the multilayer thin film of the present invention, damp heat treatment was performed on the multilayer thin film for 1,000 hours and then the property evaluation thereof was made under the condition where temperature is 85° C. and humidity is 85% as the IEC 1646 standard. The multilayer thin film was tested by using the AZO/Ag/AZO multilayer thin film containing a silver layer with a thickness of 9 nm which is excellent in figure of merit as a target. An AZO thin film with a thickness of 100 nm containing no silver layer was used as a control group.

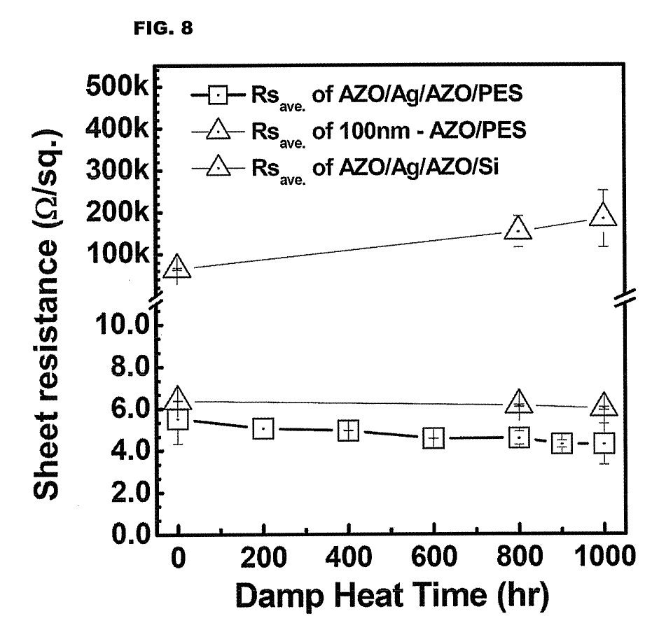

FIG. 8 is a graph illustrating the measurement result of a change in a sheet resistance according to damp heat treatment of a multilayer thin film for 1,000 hours according to one embodiment of the present invention. In FIG. 8, the sheet resistance was measured within a precision of ±0.5 Ω/sq using the four-point probe method (model CMT-SR 1000). It can be found from the graph of FIG. 8 that the sheet resistance of the AZO/Ag/AZO multilayer thin film was nearly constant without any variation even after the damp heat treatment for 1,000 hours in case of being deposited on the Si or PES substrate. Contrarily, the AZO thin film exhibited an increase in sheet resistance by about 66% after the damp heat treatment for 1,000 hours.

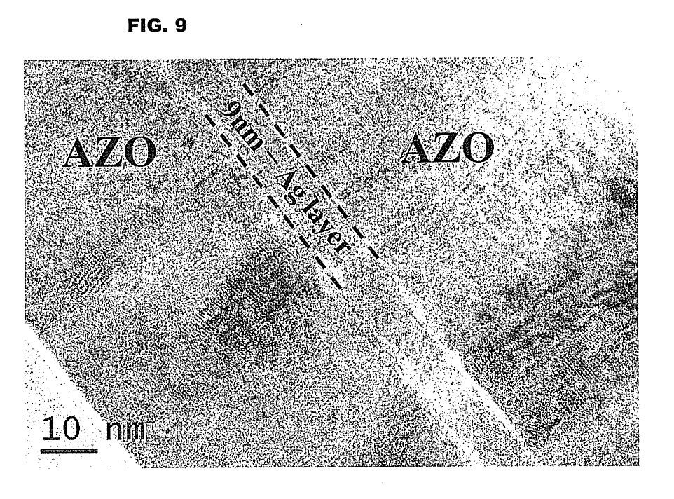

FIG. 9 is a TEM result photograph obtained by analyzing the cross-section of a multilayer thin film formed on the Si substrate after damp heat treatment of the multilayer thin film for 1,000 hours according to one embodiment of the present invention. It could be found from FIG. 9 that the Ag layer remains constant without any change even after the damp heat treatment for 1,000 hours.

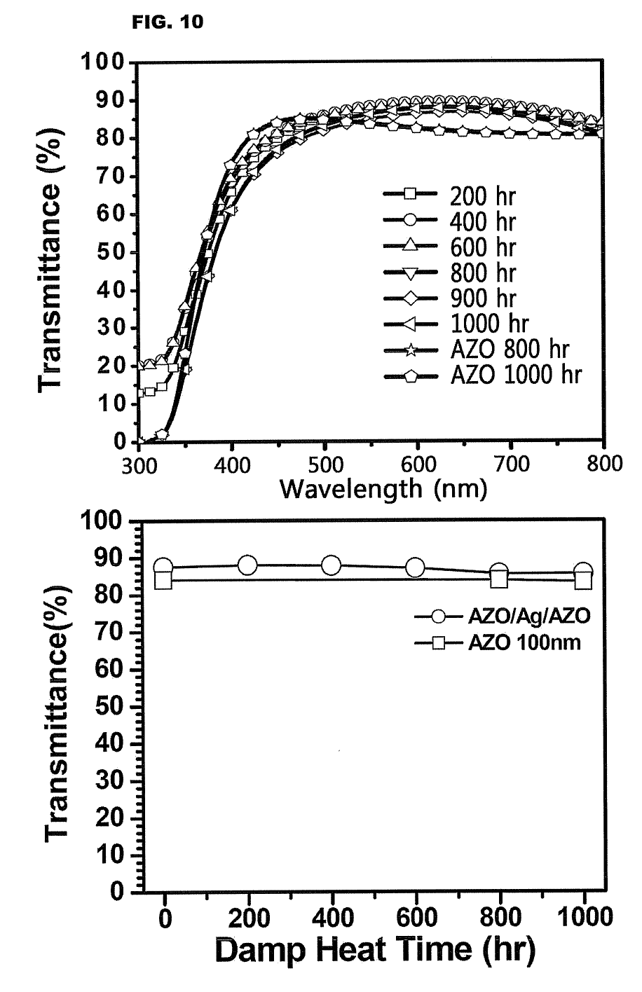

FIG. 10 shows a graph illustrating a change in light transmittance according to damp heat treatment of a multilayer thin film according to one embodiment of the present invention. In FIG. 10, the upper-side graph shows a spectrum of the transmittance at a visible light region after damp heat treatment of the multilayer thin film for 1,000 hours, and the lower-side graph shows a graph of a change in light transmittance according to damp heat time at 550nm. It can be found from FIG. 10 that the light transmittance was not affected by the damp heat treatment irrespective of whether or not the Ag layer exists.

### Embodiment 5

### Bending Test of AZO/Ag/AZO Multilayer Thin Film

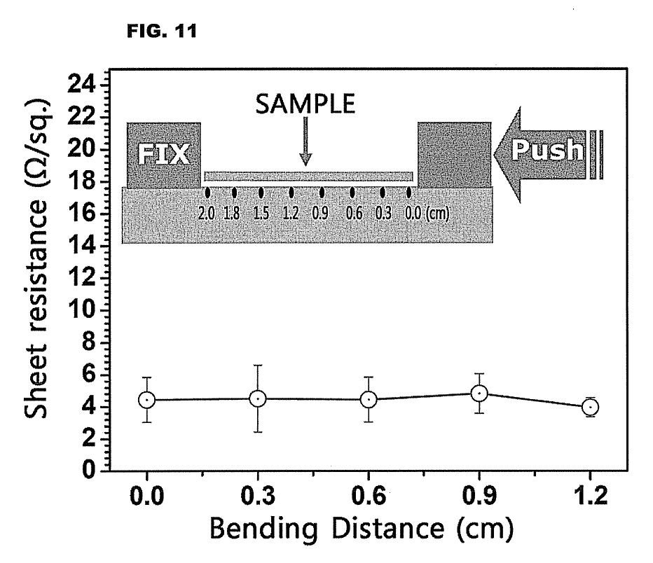

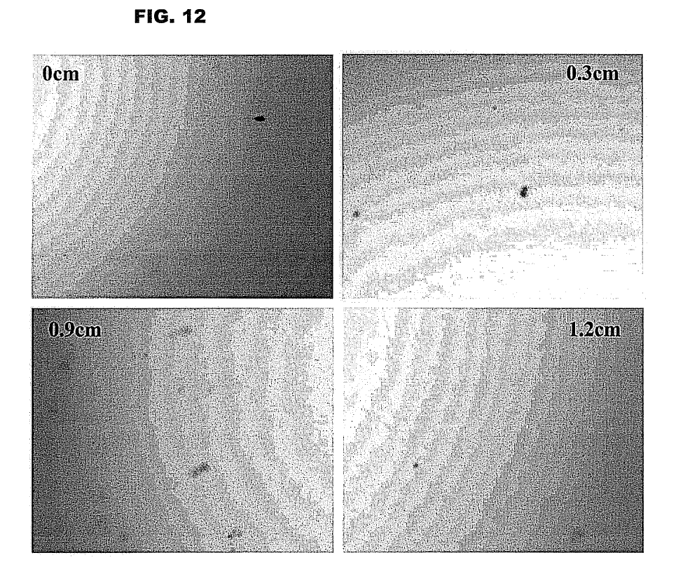

A bending test was performed to identify the adhesive force between the substrate and the multilayer thin film. That is, as shown in a schematic view shown inside the graphs of FIG. 11, one side of a sample is fixed and other side thereof is pushed in a direction where the sample is fixed. Thereafter, the pushed state of the sample is maintained for 30 seconds, and then the sheet resistance and the surface image at each position were measured and shown in FIGS. 11 and 12.

The measurement results of the sheet resistance according to the bending distance shown in FIG. 11 show no difference within an error range. FIG. 12 is a light microscope photograph taken at 300 magnifications illustrating a surface image according to a bending distance of a multilayer thin film according to one embodiment of the present invention. It can be seen from FIG. 12 that the surface images also shows no change. This indicates that although s severe bending test is performed, the multilayer thin film shows no change.

As described above, according to the present invention, it is possible to produce a transparent conducting film which exhibits a low resistivity of 10-5 Ω-cm or less and a high light transmittance of 85% or more without any thermal treatment, stability in damp heat treatment, and mechanical stability against bending stress unlike a conventional AZO/Ag/AZO multilayer thin film.

Furthermore, according to the present invention, it is possible to economically prepare a flexible transparent conducting film which exhibits a stable adhesive force on a flexible substrate while retaining the above mentioned characteristics, so that the flexible transparent conducting film can be utilized as a material of a variety of electronic devices such as a flat panel display device, a solar cell, a transparent touch panel and the like.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A method for preparing a transparent conducting film coated with an AZO/Ag/AZO multilayer thin film, the method comprising:
forming a primary AZO thin film on a substrate using an AZO target doped with Al through a sputtering method;
depositing Ag on the primary AZO thin film using the sputtering method to form a deposited Ag layer; and
forming a secondary AZO thin film on the Ag thin film using the AZO target doped with Al through the sputtering method.

2. The method according to claim 1, wherein the thickness of the deposited Ag layer ranges from 5 to 15 nm.

3. The method according to claim 2, wherein the thickness of the deposited Ag layer ranges from 7 to 11 nm.

4. The method according to claim 1, wherein the thicknesses of the primary AZO thin film and the secondary AZO thin film range from 10 to 100 nm, respectively.

5. The method according to claim 1, wherein the substrate is a glass substrate, a quartz substrate or a flexible polymer substrate.

6. The method according to claim 5, wherein the flexible polymer substrate is made of polyethersulfone, polyethylene terephthalate, Polycarbonate, polyimide, or polyethylene naphthalate.

7. A transparent conducting film coated with an AZO/Ag/AZO multilayer thin film prepared by the method according to claim 1.

8. A transparent conducting film coated with an AZO/Ag/AZO multilayer thin film prepared by the method according to claim 5.

9. A transparent conducting film coated with an AZO/Ag/AZO multilayer thin film prepared by the method according to claim 6.

10. The method according to claim 2, wherein the thicknesses of the primary AZO thin film and the secondary AZO thin film range from 10 to 100 nm, respectively.

11. The method according to claim 2, wherein the substrate is a glass substrate, a quartz substrate or a flexible polymer substrate.

12. The method according to claim 11, wherein the flexible polymer substrate is made of polyethersulfone, polyethylene terephthalate, Polycarbonate, polyimide, or polyethylene naphthalate.

13. A transparent conducting film coated with an AZO/Ag/AZO multilayer thin film prepared by the method according to claim 3.

14. A transparent conducting film coated with an AZO/Ag/AZO multilayer thin film prepared by the method according to claim 11.

15. A transparent conducting film coated with an AZO/Ag/AZO multilayer thin film prepared by the method according to claim 12.
